(19) United States
(12) Patent Application Publication
(10) Pub. No.: US 2012/0111393 A1
(43) Pub. Date: May 10, 2012

(54) INTEGRATED CARTRIDGE FOR ADHESIVE-MOUNTED PHOTOVOLTAIC MODULES

(76) Inventors: Joshua Conley, Sylvania, OH (US); John Perkins, Pittstown, NJ (US); Wenlai Feng, Perrysburg, OH (US); Thomas Truman, Toledo, OH (US); Michael Monaco, Stanhope, NJ (US); Donivan Shetterly, Bowling Green, OH (US)

(21) Appl. No.: 13/329,696

(22) Filed: Dec. 19, 2011

Related U.S. Application Data
(63) Continuation-in-part of application No. 12/957,808, filed on Dec. 1, 2010.
Application No. 12/957,808 is a continuation-in-part of application No. 12/846,621, filed on Jul. 29, 2010.
Application No. 12/846,621 is a continuation-in-part of application No. 12/846,644, filed on Jul. 29, 2010.
Application No. 12/846,644 is a continuation-in-part of application No. 12/846,686, filed on Jul. 29, 2010.

(51) Int. Cl. H01L 31/048; B32B 37/14; B32B 37/12; H01L 31/0203; B23P 11/00

(52) U.S. Cl. 136/251; 136/259; 136/252; 29/428; 156/60

(57) ABSTRACT

A photovoltaic module mounting cartridge has a frame structure for mounting a plurality of photovoltaic modules thereon, the frame structure having supports for engaging with and supporting an associated mounting rail provided on the underside of a photovoltaic module such that the photovoltaic module can be selectively installed or removed from the cartridge. A method of assembling a photovoltaic module mounting cartridge is also described, comprising providing a frame structure, providing a plurality of photovoltaic modules having at least one associated mounting rail, arranging the photovoltaic modules atop the frame structure, and attaching each associated mounting rail to the frame structure.

### RELATED APPLICATION DATA

This application is a continuation-in-part of U.S. patent application Ser. No. 12/957,808, filed Dec. 1, 2010, which is a continuation-in-part of U.S. patent application Ser. Nos. 12/846,621, filed Jul. 29, 2010, 12/846,644, filed Jul. 29, 2010, and 12/846,686, filed Jul. 29, 2010, the disclosures of which are each incorporated by reference herein in their entirety.

### FIELD OF THE INVENTION

Embodiments of the invention relate generally to photovoltaic (PV) power generation systems, and more particularly to simplifying the installation of photovoltaic modules in large-scale arrays.

### BACKGROUND OF THE INVENTION

Typically, photovoltaic power generation systems are constructed by installing a foundation system (typically a series of posts or footings) on which is constructed a module structural support frame (typically constructed of elongated beams, brackets, tables or rails, and clips), and mounting individual photovoltaic modules to the support frame with fasteners, for example, fastening clips. This is a time-consuming process, which becomes increasingly inefficient with large-scale installations.

More recently, cartridge designs have been developed, such as those disclosed in U.S. patent application Ser. Nos. 12/846,621 and 12/957,808 to Bellacicco, et al. A cartridge design, also sometimes referred to as a module carrier, permits pre-assembly of groups of photovoltaic modules onto a common frame structure which can be shipped as a unit to an installation site where they are installed as a unit on a support structure. The assembly of each cartridge, which generally involves manually mounting each photovoltaic module to the frame structure, can be consolidated at a factory. Once assembled, the cartridges can be shipped whole to an installation site and installed without the complicated and labor intensive procedures that were previously required on site to install individual photovoltaic modules.

A cartridge design that is easily manufactured is desirable.

### BRIEF DESCRIPTION OF THE DRAWINGS

FIG. 1 is a perspective view of backside of a photovoltaic module according to an exemplary embodiment.

FIG. 2 is a perspective view of a photovoltaic module mounting rail according to an exemplary embodiment.

FIG. 2A is a perspective view of a photovoltaic module mounting rail blank according to an exemplary embodiment.

FIG. 2B is a perspective view of a photovoltaic module mounting rail blank according to an exemplary embodiment.

FIGS. 3A and 3B are respective top-down views of a completely and partially loaded cartridge according to an exemplary embodiment.

FIG. 3C is a top-down view of a completely loaded cartridge according to another exemplary embodiment.

FIG. 4A is a cross-sectional view of side beams of a cartridge frame according to an exemplary embodiment.

FIG. 4B is a cross-sectional view of the top and bottom beams of a cartridge frame according to an exemplary embodiment.

FIG. 4C is a cross-sectional view of side beams of stacked cartridges according to an exemplary embodiment.

FIG. 4D is an end view of the center beam of a cartridge frame according to an exemplary embodiment.

FIG. 4E is a cross-sectional view of a center beam of a cartridge frame according to an exemplary embodiment.

FIG. 4F is a perspective view of one end of a side beam of a cartridge frame according to an exemplary embodiment.

FIG. 5A is a top perspective view of a wiring structure for a cartridge frame according to an exemplary embodiment.

FIG. 5B is a cross-sectional view of a center beam of a cartridge frame according to an exemplary embodiment.

FIG. 6 is a perspective view of a corner joining element of a cartridge frame according to an exemplary embodiment.

FIG. 7 is a cross-sectional view of center and side beam of a cartridge frame showing a loaded photovoltaic module according to an exemplary embodiment.

FIG. 7A is a cross-sectional view of center and side beam of a cartridge frame showing a loaded photovoltaic module according to an exemplary embodiment.

FIG. 7B is a cross-sectional view of center and side beam of a cartridge frame showing a loaded photovoltaic module according to an exemplary embodiment.

FIG. 8A is a side view of a side beam of a cartridge frame and wheel assembly according to an exemplary embodiment.

FIG. 8B is an end view of a wheel assembly for a cartridge frame according to an exemplary embodiment.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

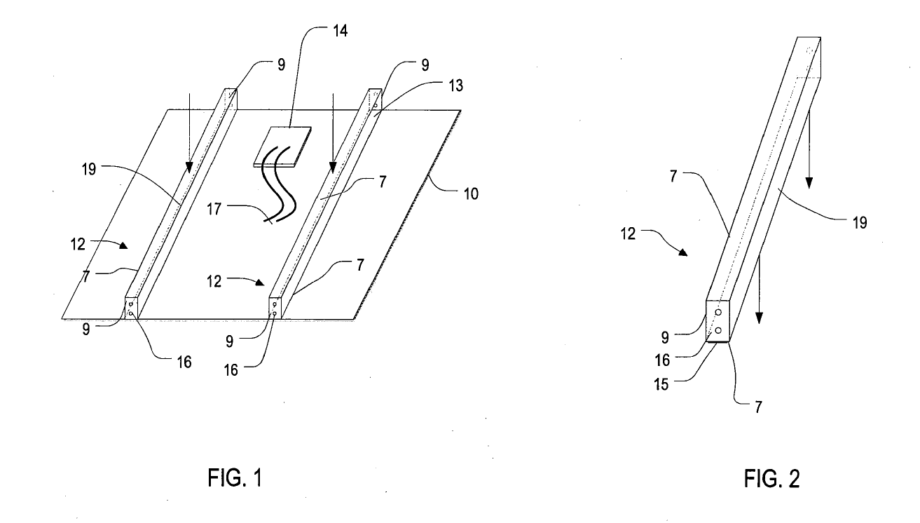

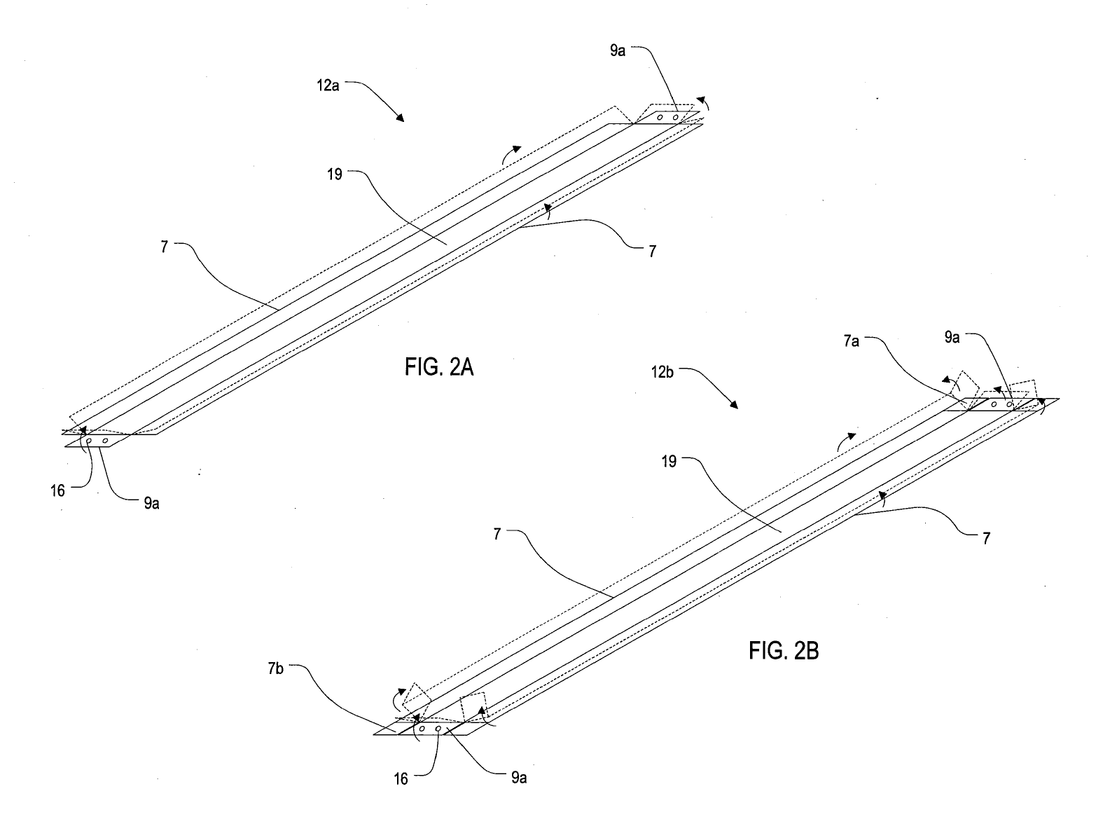

FIG. 1 illustrates the underside of a photovoltaic module 10 having a pair of mounting rails 12 installed thereon. The mounting rails 12, one being shown in FIG. 2, are generally arranged spaced apart from each other so as to not impede conductors 17 exiting a module underside mounted cord plate 14. The mounting rails 12 are arranged equidistantly from each other in a longitudinal direction. Although two mounting rails 12 are shown in FIG. 1, any number could be used depending on the configuration of photovoltaic module 10.

The mounting rails 12 are illustrated with one longitudinal side 7 down and another longitudinal side 7 up in FIGS. 1 and 2. Each mounting rail 12, which is generally a hollow metallic structure, has two longitudinal sides 7, two upstanding ends 9, one closed back surface 19, one open side 13, and one or more mounting holes 16 in each of the upstanding ends 9 through which a fastener, such as, e.g., a screw, pin, bolt, or rivet, could pass. The open side 13 of the mounting rails 12 allows access for the fasteners as will be described in greater detail below. Two mounting holes 16 for each upstanding end 9 are shown in FIG. 2, but it should be understood that any number could be used, and further, mounting holes 16 can be threaded screw holes or holes provided with integral bolts.

The mounting rails 12 are mounted to photovoltaic module 10 by applying an adhesive 15, such as a polymer glue or very high adhesive bond tape, to one longitudinal side 7 of the mounting rail 12, which faces the photovoltaic module 10 in FIG. 1, and pressing the mounting rail 12 to the photovoltaic module 10 in the direction of the arrows in FIGS. 1 and 2. Of course, it should be understood that the adhesive 15 could be applied to the underside of the photovoltaic module 10 instead of, or in addition to, the adhesive 15 applied to a longitudinal side 7 of the mounting rail 12. In the embodiment shown in FIG. 1, the two mounting rails 12 are adhered to the photovoltaic module 10 such that the closed, back surfaces 19 of the mounting rails 12 face towards each other. In another embodiment, mounting rails 12 can be adhered such that the closed, back surfaced 19 of the mounting rails 12 face away from one another. It should also be understood that the adhesive 15 could be applied to either longitudinal side 7 of the mounting rail 12 as desired.

FIGS. 2A and 2B show mounting rail blanks 12a, b from which the mounting rails 12 of FIGS. 1 and 2 can be formed. In one embodiment, shown in FIG. 2A, each upstanding end 9 of FIG. 2 is formed from a corresponding end tab 9a of the back surface 19 that is bent upwardly by 90° to the back surface 19 to align with longitudinal sides 7 that are also upwardly bent by 90° relative to back surface 19. In one embodiment, the joint where the bent longitudinal sides 7 and the end tab 9a meet may be welded or otherwise fastened to one another. In another embodiment, the bent longitudinal sides 7 need not be welded or otherwise fastened to the tabs 9a.

In another embodiment shown in FIG. 2B, each upstanding end 9 is a three-tab design formed from one end tab 9a of the back surface 19 that is bent at a 90° angle to the back surface 19 and two side tabs 7a, b of the longitudinal sides 7 that are bent at a 90° angle to the longitudinal sides 7. The end tab 9a may be bent to overlap the side tabs 7a, b in one embodiment. In an alternative embodiment, the side tabs 7a, b may be bent to overlap the end tab 9a. In the embodiments, the mounting holes 16 may be formed through the upstanding end 9 such that they extend through all tabs that form the upstanding end 9 either before or after the sides and tabs 7, 7a,b, 9a are bent into position.

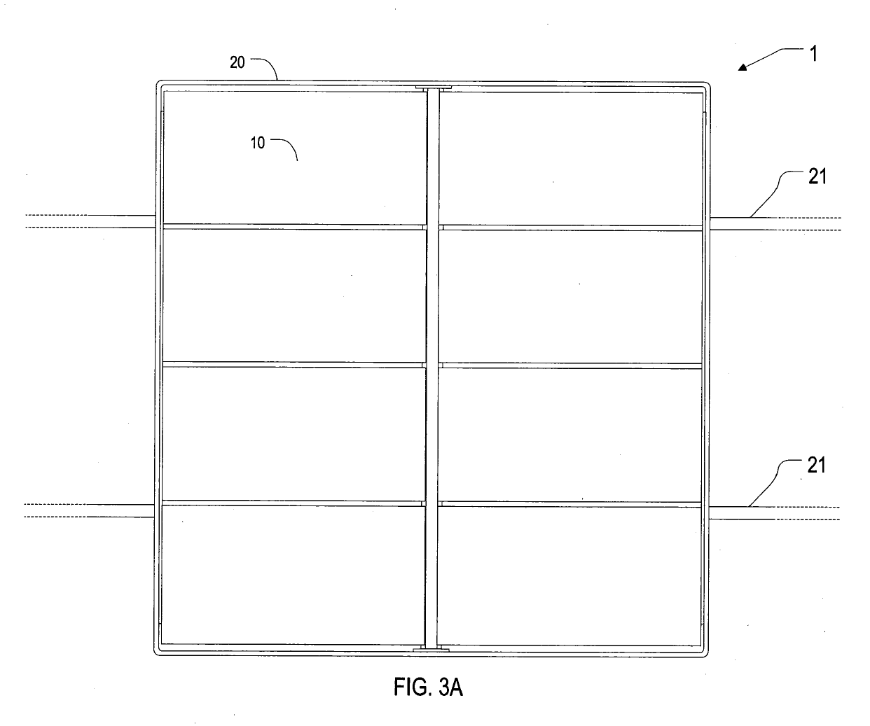

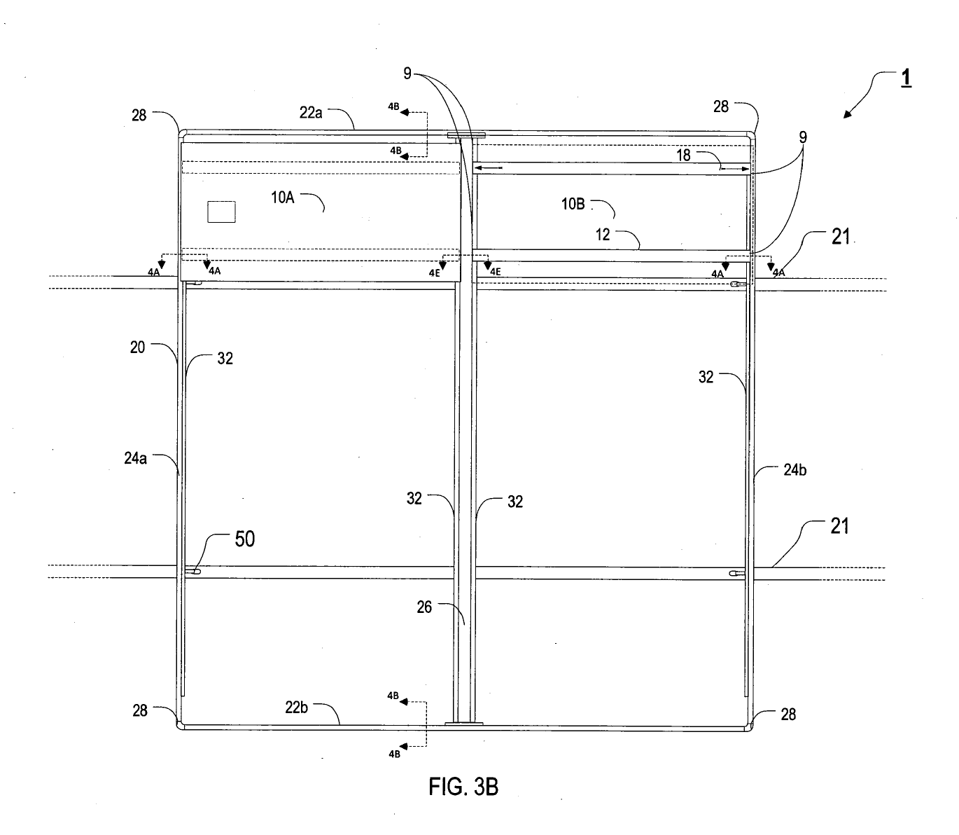

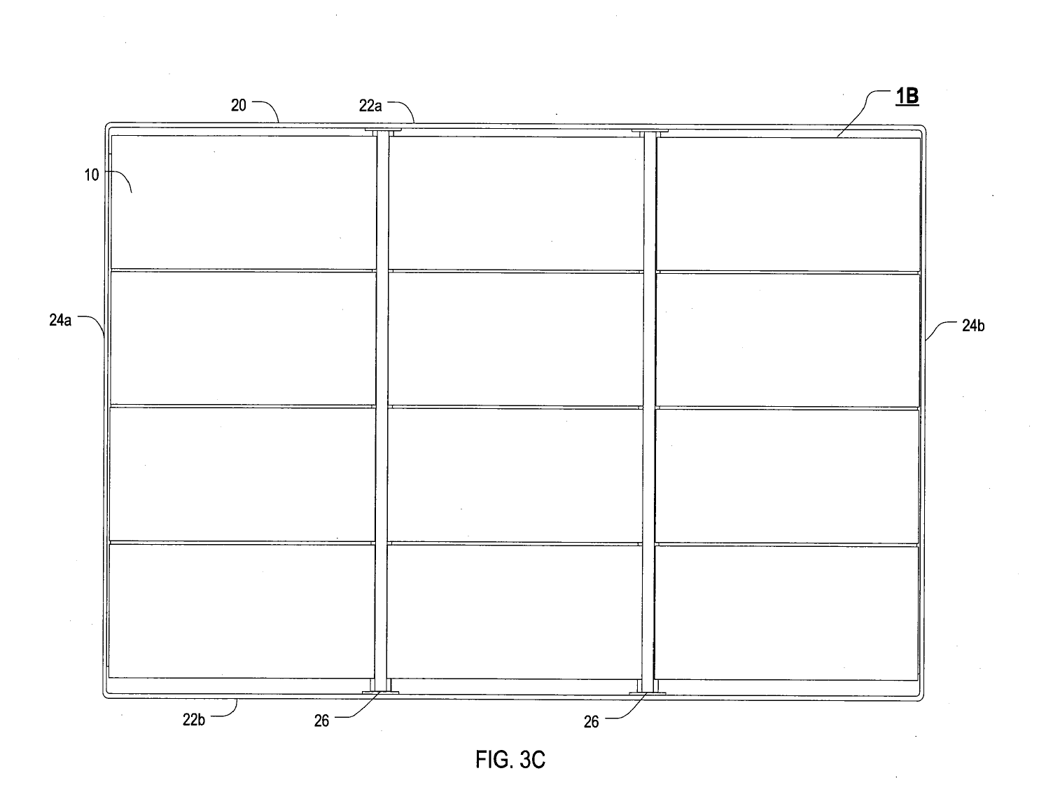

FIG. 3A illustrates a completely loaded cartridge 1 with eight photovoltaic modules 10, each with underside mounted rails 12, mounted to a frame structure 20 in an array of rows and columns. In FIG. 3A, an array of two columns and four rows of photovoltaic modules 10 is shown with the upper “sunny side” surface being shown. The cartridge 1 is mounted and installed on parallel cartridge mounting rails 21. Mounting rails 21 may be provided on a ground or roof support structure.

FIG. 3B illustrates a cartridge 1 loaded with two modules 10A, 10B so that more detail of the frame structure 20 can be seen. The frame structure 20 comprises top and bottom beams 22a, 22b and first side and second side beams 24a, 24b, joined at the corners by corner joining elements 28 (which are shown in more detail in FIG. 6). The cartridge 1 also comprises a center beam 26 mounted between the top and bottom beams 22a, 22b. Each of the side beams 24a, 24b as well as the center beam 26 has mounting ridges 32 for receiving and supporting opposite ends of each of the associated mounting rails 12 of a photovoltaic module 10. The side beams 24a, 24b each have one mounting ridge 32, while the center beam 26 has two mounting ridges 32, one on each of its opposite sides.

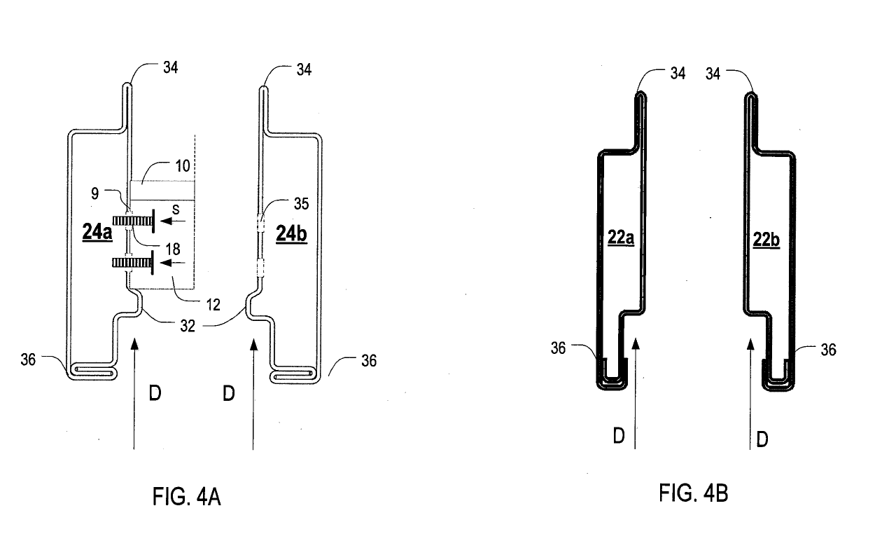

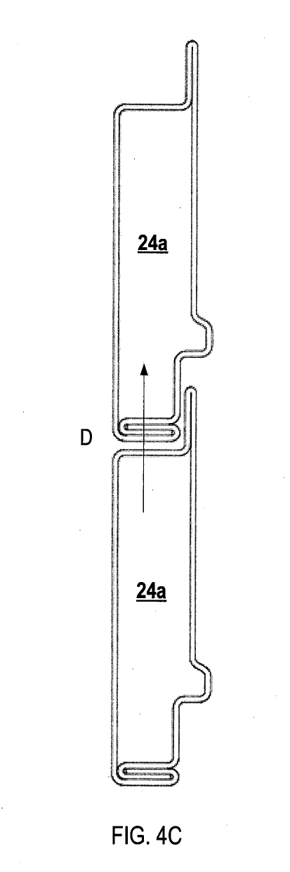

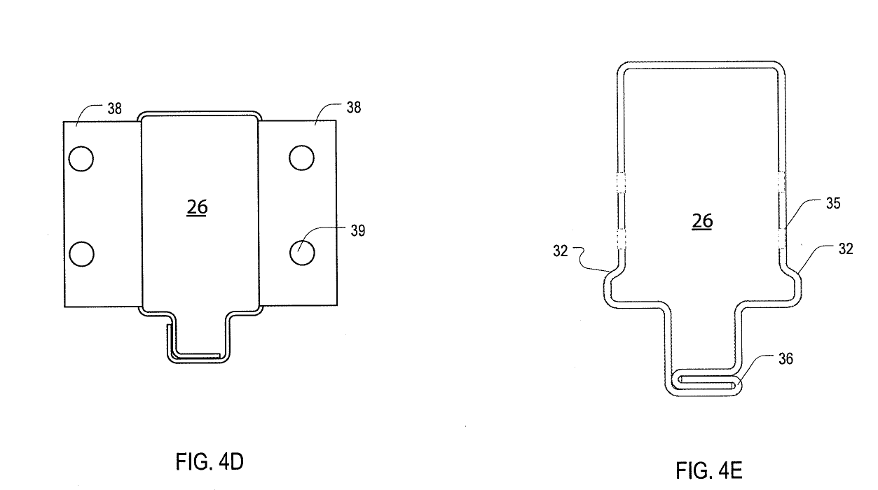

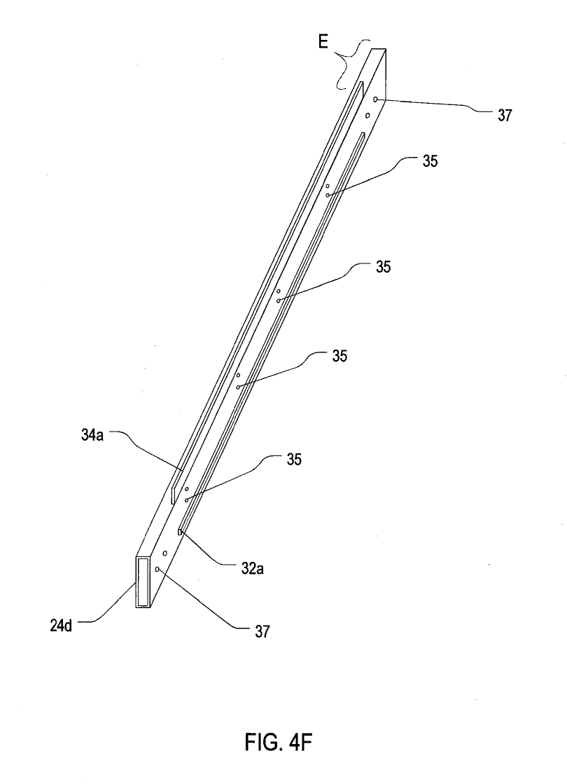

FIG. 3B shows a first photovoltaic module 1 OA in place between first side beam 24a and center beam 26 and a second photovoltaic module 10B between the second side beam 24b and center beam 26. Photovoltaic module 10B is shown transparently, so that the corresponding pair of mounting rails 12 can be better seen to illustrate how a photovoltaic module 10 is mounted to the cartridge 1. Module 10B, when mounted, has the ends 9 of its associated mounting rails 12 positioned on the ridges 32 of the second side beam 24b and center beam 26. Fasteners 18 are passed through the mounting holes 16 and into corresponding mounting holes 35 (shown in FIG. 4D) in the center beam 26 and second side beam 24b. As noted, the fasteners 18 may be screws, pins, bolts, or rivets. The fasteners 18, e.g. screws, are received through the open side of the mounting rails 12 when the modules 10 are placed on the cartridge 1. In this particular embodiment as noted above the rails 12 are hollow and open on one side 13 as illustrated in FIG. 2. The mounting holes 35 can be unthreaded holes, threaded screw holes, or holes provided with integral bolts provided on the first and second side beams 24a, 24b and the center beam 26. The mounting holes 35 on the first and second side beams 24a, 24b and the center beam 26 are spaced lengthwise along the beams 24a, 24b, 26 so as to allow the rails 12 attached to the photovoltaic modules 10 to be properly installed on the frame structure 20.

In a completely loaded cartridge 1, such as shown in FIG. 3A, each photovoltaic module 10 is mounted between one of the first and second side beams 24a, 24b and the center beam 26. Of course, it should be understood that the lengths of the various beams 22a, 22b, 24a, 24b and 26 can be modified to accommodate any size or number of photovoltaic modules 10, or for a different mounting arrangement than that shown. Multiple center beams 26 can also be used, as is shown in FIG. 3C, so as to permit the mounting of more than two columns of photovoltaic modules 10 on the cartridge 1.

FIGS. 4A, 4B, 4C, 4D, and 4E show elements of beams 22a, 22b, 24a, 24b and 26 in more detail. FIG. 4A shows a cross-section of the first and second side beams 24a, 24b along line 4A-4A of FIG. 3B. FIG. 4B shows a cross section of an exemplary top and bottom beam 22a, 22b along 4B-4B of FIG. 3B. FIG. 4C shows cross sections of stacked exemplary side beams 24a according to a disclosed embodiment. FIG. 4D shows a end view of the center beam 26. FIGS. 4E shows a cross-section of center beam 26 along 4E-4E of FIG. 3B. Each of beams 22a, 22b, 24a, 24b and 26 is generally hollow and constructed from a rolled metal, such as galvanized steel. A reinforced area 36 formed of folded over metal is provided at a bottom part of each beam 22a, 22b, 24a, 24b, 26 and extends the entire length of the beams to provide increased stability and torsion resistance. Of course, the reinforced area 36 could also be located at a top of beam 22a, 22b, 24a, 24b, 26. Additionally, as noted above, each of the first and second side beams 24a, 24b and center beam 26 have mounting ridges 32 in the form of protrusions that extend outward from and along the length of beams 24a, 24b, 26 to receive and support the module mounting rails 12. The module mounting rails 12 rest on top of the mounting ridges 32 between beams 24a, 24b, 26.

FIG. 4A shows an end part of a mounting rail 12 associated with a photovoltaic module 10 interfacing one of the side beams 24a. As can be seen in FIG. 4A, a fastener 18 passes through mounting hole 16 in the upstanding end 9 of the mounting rail 12 and is driven in a direction S into a corresponding mounting hole 35 in the side beam 24a.

As is also shown in FIGS. 4A and 4B, each of top and bottom beams 22a, 22b and first side and second side beams 24a, 24b also have an upwardly extending stabilizing flange 34 which is configured to engage the underside (in a direction D, as shown in FIG. 4A) of a corresponding top and bottom beam 22a, 22b or first side and second side beam 24a, 24b in another cartridge 1. This permits cartridges 1 to be securely stacked, one atop another, following manufacturing and for transportation. FIG. 4C illustrates cartridge stacking in more detail, showing one side beam 24a stacked atop another side beam 24a of another cartridge 1. The stabilizing flange 34, which extends around substantially the entire outer rim of a cartridge 1, further serves to protect around the periphery of the cartridge 1 and the photovoltaic modules 10 mounted on the cartridge 1.

FIG. 4D shows a pair of mounting flanges 38 provided at each end of center beam 26. The mounting flanges 38 each extend outward and perpendicularly from the beam 26 and have mounting holes 39 for affixing the center beam 26 to and between the top and bottom beams 22a, 22b with fasteners.

In another embodiment, shown in the exemplary beam 24d in FIG. 4F, stabilizing flange 34a and/or mounting ridge 32a may terminate at a distance E from the end of a beam 24d to permit an oversized corner joining element to slide over the associated end of the beam 24d. In order to facilitate this, the stabilizing flange 34a and/or mounting ridge 32a are separate elements affixed to the beam 24d, rather than the integral elements as shown, for example, in FIG. 4A. Corresponding mounting holes 37 for alignment with the holes 38 of joining elements 28 are also provided on the exemplary beam 24d.

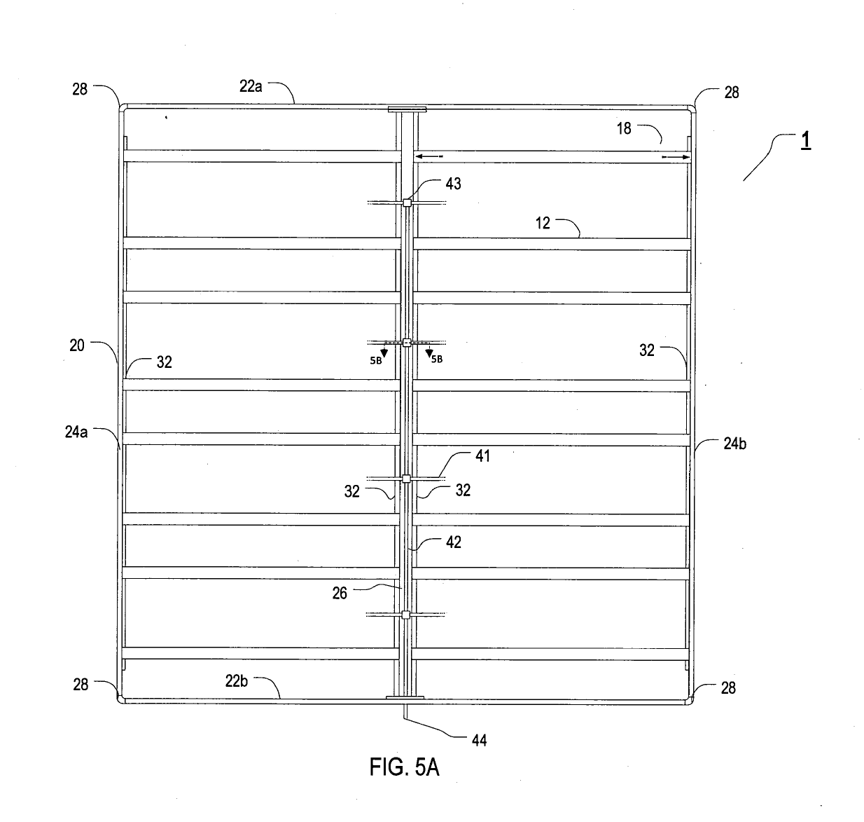

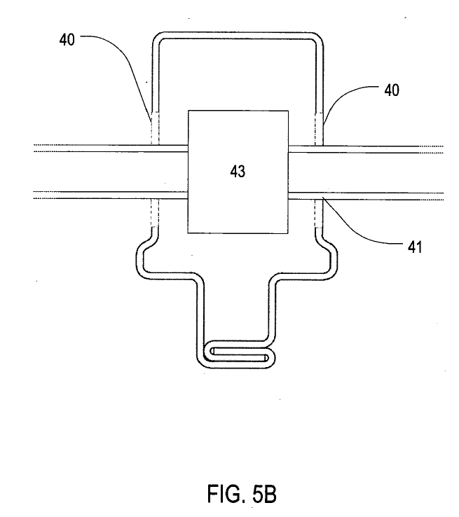

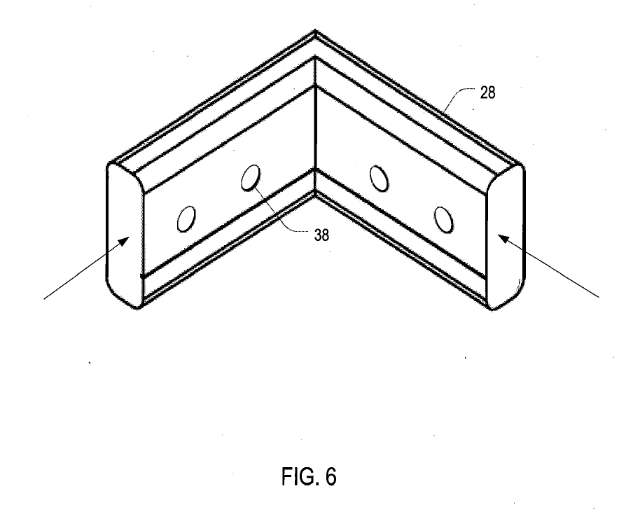

In one embodiment shown in FIGS. 5A and 5B, the center rail may act as a wiring conduit, allowing branches 41 from a common electrical bus 42 that extends along and within the center beam 26 of the cartridge 1 to connect to each photovoltaic modules 10 through connector blocks 43. FIG. 5B is a cross-section of the center beam 26 along line 5B-5B of FIG. 5A. The common electrical bus 42 acts to route the electricity generated by each photovoltaic module 10 on the cartridge 1 to a common attachment point 44. In this embodiment, wiring access holes 40 are formed on both sides of the center rail, as shown in FIG. 5B, to allow the electrical bus 42 to access the conductors 17 for each photovoltaic module 10 mounted to either side of the center beam 26 as shown in FIGS. 3A and 3B.

The top and bottom beams 22a, 22b and first side and second side beams 24a, 24b are joined at their corners by corner joining elements 28, shown in FIG. 6. The ends of the corner joining element 28 are configured to be inserted into the ends of each of one of the top or bottom beams 22a, 22b and first side or second side beams 24a, 24b and secured thereto by fasteners 18 having a shaft inserted through holes 38. In one embodiment, shown in FIG. 6, the corner joining element 28 is a solid element. In another embodiment, the corner joining element 28 is hollow. In this embodiment, the corner joining element 28 may be undersized at its ends compared to the side and bottom beams 22a, 22b, 24a, 24b so that the corner joining element can be inserted into the beams 22a, 22b, 24a, 24b. In the alternative, the corner joining element 28 may be oversized compared to the side and bottom beams 22a, 22b, 24a, 24b and hollow, so that the beams 22a, 22b, 24a, 24b can be inserted into the corner joining element 28.

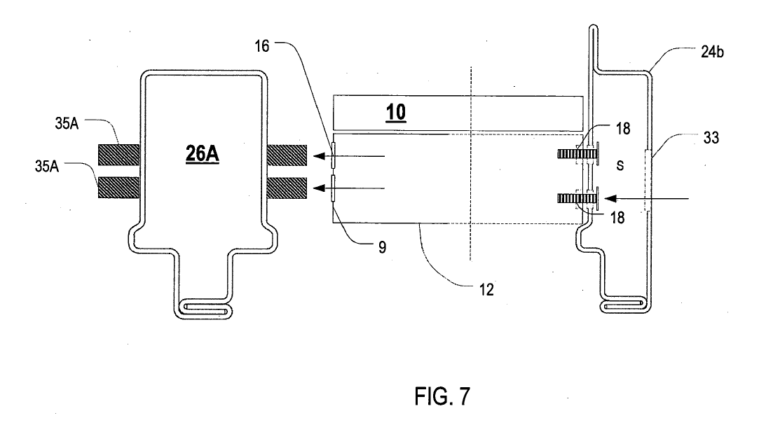

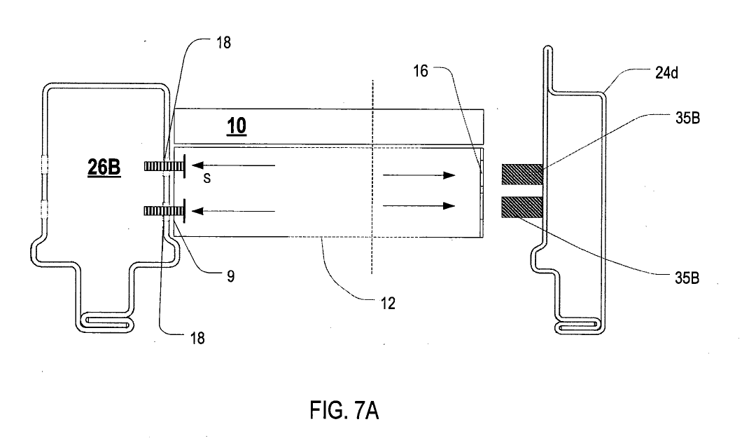

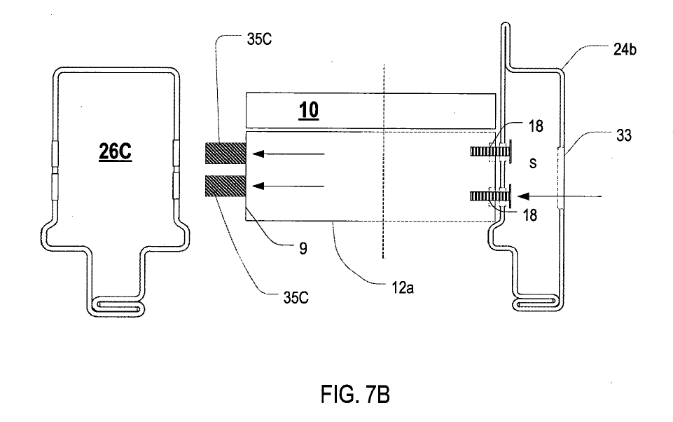

FIG. 7 shows an alternate configuration for a center beam 26A that employs mounting posts 35A instead of mounting holes 35. In use, the holes 16 of one end of the rails 12 of a photovoltaic module are slid over the posts 35A. Consequently, only one end 9 of each mounting rail 12 needs to be secured to the cartridge 1 with one or more fasteners 18. FIG. 7 also shows an alternative way to fasten rails 12 to the cartridge 1. Openings 33 may be provided in the walls of a beam (e.g. side beam 24b being shown in FIG. 7) through which fasteners 18 can be inserted in the direction S to pass into the holes 16 provided in the ends 9 of the rails 12. In this manner, a cartridge 1 can be assembled without having to pass any fasteners 18 into the cartridge 1 from the underside of the cartridge 1. In another embodiment shown in FIG. 7A, the mounting posts 35B may be employed on a side beam, such as side beam 24d and the fasteners 18 employed on the center beam 26B. In a third embodiment shown in FIG. 7B, the mounting posts 35C may be employed on one end of the mounting rails 12a and configured to be inserted to respective mounting holes on the center beam 26C. In the embodiment shown in FIG. 7B, fasteners 18 may be used on the second end of the mounting rail 12a as described with respect to FIG. 7.

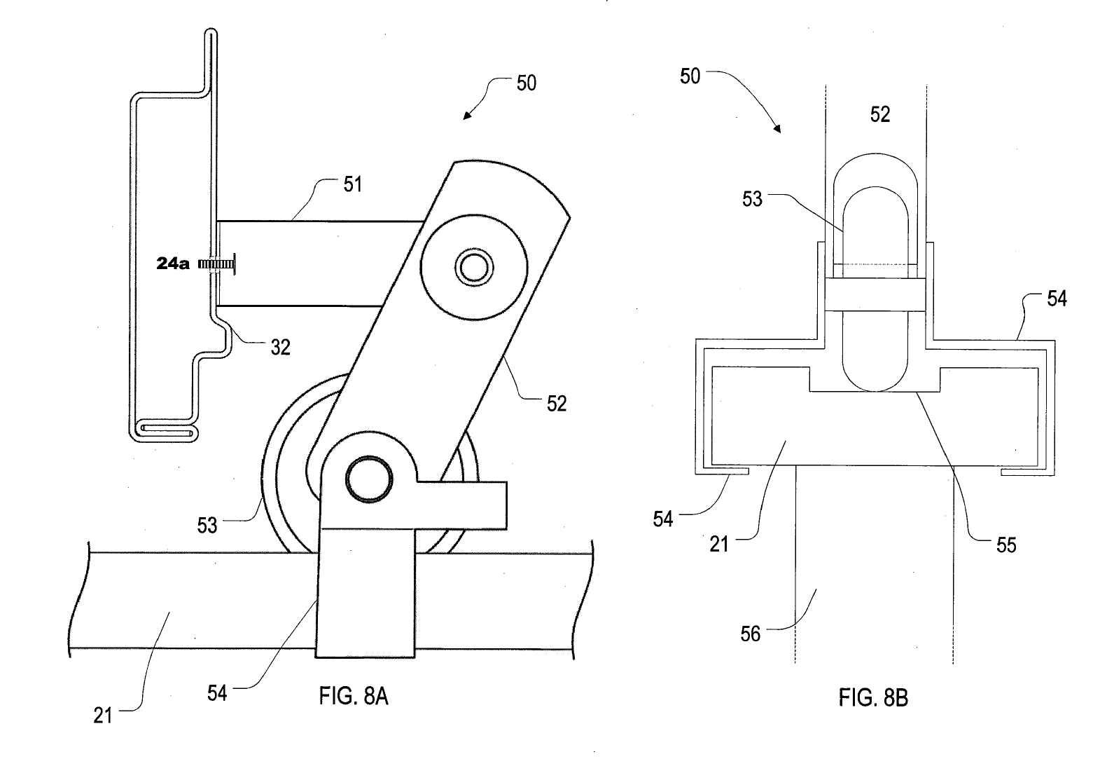

FIGS. 8A and 8B show, from a side view and end view respectively, a wheel assembly 50 that may be used as an attachment structure to allow the cartridge to slide along the cartridge mounting rails 21, shown in FIG. 3A. This enables the cartridge 1 to easily slide in a mounted position along cartridge mounting rails 21 to an installed position. The wheel assembly 50 is mounted to the side rails (e.g. side rail 24a) as is shown in FIG. 8A at locations corresponding to that of the cartridge mounting rails 21. If two mounting rails 21 are provided, four wheel assemblies 50, two on each side of cartridge 1 are provided. The cartridge mounting rails 21 and module mounting rails 12 are configured as can be seen in one embodiment in FIGS. 3A and 3B so that the wheel assemblies 50 are provided between module mounting rails 12 such that sufficient clearance exists between the underside of the photovoltaic module and the wheel assembly 50 to permit the wheel assembly's operation. In one embodiment, the wheel assembly 50 is assembled from a mounted portion 51, which is affixed to the side rail 24a, and a hinged portion 52, which is connected to the wheel 53. This construction enables the wheel assembly 50 to be placed in a storage position to enable the cartridge 1 to be stacked on other cartridges. When the cartridge 1 is ready to be installed, the hinged portion 52 is moved from the storage position and locked into a mounting position such that the mounted portion 51 rests on the hinged portion 52, which wraps underneath the mounted portion 51, to prevent the side rail 24a from resting on the cartridge mounting rail 21. In other embodiments, the wheel assembly 50 may be mounted to the outside of the side rail 24a or may be mounted below the mounting ridge 32.

As is shown in FIG. 8B, the wheel 53 is configured to follow a channel 55 in the rail 21. The wheel assembly 50 also includes a wheel bracket 54 that wraps around the rail 21 to prevent the cartridge 1 from lifting off of the rail 21, but allow the wheel assembly 50 to slide over the mounting rail supports 56 that are used to affix the mounting rails 21 to the ground, a roof, or other structure that provides a foundation. It can be appreciated that other attachment structures from the wheel assembly 50 may be used, such as ball bearings or low friction surfaces, as described in U.S. patent application Ser. No. 12/846,646.

The above described cartridges 1 (FIGS. 3A and 3B), 1B (FIG. 3C) can be easily machine assembled, although manual assembly is also possible, in a process which has the photovoltaic modules 10 with the mounting rails 12 installed as an array of modules atop an assembled cartridge 1. Because each photovoltaic module 10 is individually attached to the cartridge 1 by its own mounting rails 12, selective installation and removal of a each photovoltaic module is possible simply by attaching or detaching the corresponding fasteners 18. Advantageously, the cartridges 1 (FIGS. 3A, 3B) or 1B (FIG. 3C) do not have to be disassembled to replace a single photovoltaic module 10 in the field.

While several embodiments have been described in detail, it should be readily understood that the invention is not limited to the disclosed embodiments. Rather the embodiments can be modified to incorporate any number of variations, alterations, substitutions or equivalent arrangements not heretofore described. Although certain features have been described with some embodiments of the cartridge, such features can be employed in other embodiments of the cartridge as well. Accordingly, the invention is not limited by the foregoing description, but is only limited by the scope of the appended claims.

What is claimed as new and desired to be protected by Letters Patent of the United States is:

1. A photovoltaic module mounting cartridge, comprising:
a frame structure for mounting a plurality of photovoltaic modules thereon in an array, the frame structure having supports for engaging with and supporting a mounting rail provided on the underside of each photovoltaic module such that the photovoltaic module can be selectively installed or removed from the cartridge.

2. The photovoltaic module mounting cartridge of claim 1, wherein the frame structure comprises:
a top beam;
first and second side beams;
a bottom beam; and
a center beam between the top and bottom beams.

3. The photovoltaic module mounting cartridge of claim 2, wherein the top and bottom beams are joined to each of the, first and second side beams.

4. The photovoltaic module mounting cartridge of claim 3, wherein the frame structure further comprises corner joining elements between:
the top beam and first side beam;
the top beam and second side beam;
the bottom beam and first side beam; and
the bottom beam and second side beam.

5. The photovoltaic module mounting cartridge of claim 2, wherein supports are provided at the first and second side beams and at the center beam such that photovoltaic modules can be supported between the center beam and each of the first and second side beams.

6. The photovoltaic module mounting cartridge of claim 5, wherein the supports of the first and second side beams and the center beam are mounting ridges atop which mounting rails can rest.

7. The photovoltaic module mounting cartridge of claim 6, wherein the mounting ridges are on an inside surface of each of the first and second side beams and on opposing side surfaces of the center beam.

8. The photovoltaic module mounting cartridge of claim 7, further comprising a plurality of photovoltaic modules mounted thereon, each photovoltaic module having a plurality of mounting rails on an underside surface which rests on the supports.

9. The photovoltaic module mounting cartridge of claim 8, wherein end sides of the module mounting rails include one or more mounting holes for receiving a fastening element for affixing the mounting rails to the frame structure.

10. The photovoltaic module mounting cartridge of claim 9, wherein the first and second side beams and the center beam each have a plurality of mounting holes for receiving a fastening element.

11. The photovoltaic module mounting cartridge of claim 10, wherein the mounting holes on the first and second side beams and the center beam are threaded screw holes.

12. The photovoltaic module mounting cartridge of claim 9, wherein the first and second side beams have a plurality of mounting holes, and the center beam has a plurality of corresponding mounting posts which are configured to engage the mounting holes on the end sides of the mounting rails.

13. The photovoltaic module mounting cartridge of claim 9, wherein the first and second side beams have a plurality of mounting posts which are configured to engage the mounting holes on the end sides of the mounting rails, and the center beam has a plurality of mounting holes for receiving a fastening element.

14. The photovoltaic module mounting cartridge of claim 8, wherein the center beam has a plurality of mounting holes which are configured to engage a plurality of mounting posts on the end sides of the mounting rails.

15. The photovoltaic module mounting cartridge of claim 2, wherein each of the top, bottom, first side, second side and center beams are hollow.

16. The photovoltaic module mounting cartridge of claim 2, wherein each of the top, bottom, first side, second side and center beams comprise a rolled metallic structure.

17. The photovoltaic module mounting cartridge of claim 2, wherein each of the top, bottom, first side, second side and center beams have a longitudinally extending reinforced area.

18. The photovoltaic module mounting cartridge of claim 17, wherein the reinforced area is at one of the top or bottom of each of the top, bottom, first side, second side and center beams.

19. The photovoltaic module mounting cartridge of claim 2, wherein each of the top, bottom, first side and second side beams have an upwardly extending flange which is configured to engage an underside of a corresponding top, bottom, first side or second side beam of another photovoltaic module mounting cartridge to facilitate stacking of cartridges.

20. The photovoltaic module mounting cartridge of claim 2, wherein the center beam has end mounting flanges for attaching to the top and bottom beams.

21. The photovoltaic module mounting cartridge of claim 20, wherein the end mounting flanges of the center beam have mounting holes through which a fastener may be passed to attach the center beam to each of the top and bottom beams.

22. The photovoltaic module mounting cartridge of claim 7, wherein the frame structure comprises a plurality of spaced center beams between the top and bottom beams.

23. The photovoltaic module mounting cartridge of claim 2, further comprising a plurality of photovoltaic modules attached to the frame structure, wherein the mounting rails of the photovoltaic modules are attached to the frame structure between either of the first or second side beams and the center beam.

24. The photovoltaic module mounting cartridge of claim 23, further comprising a second center beam and wherein a plurality of photovoltaic modules attached to the frame structure are attached between the two center beams.

25. The photovoltaic module mounting cartridge of claim 8, wherein the mounting rails are hollow.

26. The photovoltaic module mounting cartridge of claim 8, wherein the mounting rails are affixed to an associated bottom surface of each photovoltaic module.

27. The photovoltaic module mounting cartridge of claim 26, wherein the mounting rails are affixed to the associated bottom surface by an adhesive.

28. The photovoltaic module mounting cartridge of claim 27, wherein the adhesive is a bond tape.

29. The photovoltaic module mounting cartridge of claim 8, wherein end sides of the mounting rails include one or more mounting holes through which a fastener can pass to attach the mounting rail to the frame structure.

30. The photovoltaic module mounting cartridge of claim 2, further comprising a plurality of structures affixed to the side beams for facilitating sliding installation of the mounting cartridge along a support rail.

31. The photovoltaic module mounting cartridge of claim 30, wherein the structures comprise a wheel.

32. The photovoltaic module mounting cartridge of claim 30, wherein the structures are hinged to enable the attachment structure to move. from a storage position which permits cartridge stacking to an installation position which permits sliding movement along the support rail.

33. The photovoltaic module mounting cartridge of claim 31, wherein the wheel is positioned so as to engage a corresponding groove in the support rail.

34. The photovoltaic module mounting cartridge of claim 23, wherein the center beam provides a conduit containing an electrical bus..

35. The photovoltaic module mounting cartridge of claim 34, wherein the center beam comprises an access hole to allow conductors of a photovoltaic module mounted on the mounting cartridge to connect to the electrical bus.

36. The photovoltaic module mounting cartridge of claim 34, further comprising a connector block, wherein the connector block enables photovoltaic module wiring from a photovoltaic module mounted on a first side of the center beam to access a central wiring harness of the photovoltaic module mounting cartridge.

37. The photovoltaic module mounting cartridge of claim 36, wherein the connector block is configured to enable the photovoltaic module wiring from a second photovoltaic module mounted on a second side of the center beam to access the central wiring harness of the photovoltaic module mounting cartridge.

38. An apparatus comprising:
a photovoltaic module;
at least one mounting rail affixed to an underside of the photovoltaic module,
wherein the mounting rail is configured to mount the photovoltaic module to a mounting cartridge configured to mount a plurality of photovoltaic modules.

39. The apparatus of claim 38, wherein the mounting rail extends along a longitudinal extent of the photovoltaic module.

40. The apparatus of claim 38, wherein the mounting rail comprises a back side, a first and second longitudinal side, a first and second upstanding end, and an open side.

41. The photovoltaic module of claim 38, wherein the mounting rail comprises a plurality of mounting holes on an end surface configured to receive a fastener.

42. The apparatus of claim 38, wherein the mounting rail comprises a plurality of mounting posts configured to be inserted into mounting holes on the mounting cartridge.

43. The apparatus of claim 38, wherein the mounting rails are affixed to the photovoltaic module by an adhesive.

44. The apparatus of claim 40, wherein the first longitudinal side is affixed to an underside of the photovoltaic module.

45. The apparatus of claim 38, further comprising a plurality of fasteners configured to be inserted through the upstanding ends and into the mounting cartridge.

46. The apparatus of claim 40, wherein the first upstanding end is formed from a tab extending from the back side folded at a first angle relative to the back side.

47. The apparatus of claim 40, wherein the first upstanding end is formed from a first tab extending from the back side folded at a first angle relative to the back side, a second tab extending from the first longitudinal side, and a third tab extending from the second longitudinal side.

48. The apparatus of claim 47, wherein the first tab is folded over the second and third tabs.

49. The apparatus of claim 47, wherein the second and third tabs are folded over the first tab.

50. The apparatus of claim 40, comprising a first and second mounting rail extending along a longitudinal extent of the photovoltaic module, wherein the first mounting rail is parallel to the second mounting rail.

51. A method of assembling a photovoltaic module mounting cartridge, comprising:
providing a frame structure;
providing a plurality of photovoltaic modules, each having at least one mounting rail affixed to a bottom surface thereof;
arranging the photovoltaic modules atop the frame structure in an array of rows and columns; and
attaching each associated mounting rail to the frame structure to secure the corresponding photovoltaic module on the frame structure.

52. The method of claim 51, wherein providing the frame structure comprises:
providing a top beam;
providing first and second side beams;
providing a bottom beam; and
providing at least one center beam between the top and bottom beams.

53. The method of claim 52, wherein providing the frame structure further comprises joining each of the top and bottom beams to each of the first and second side beams.

54. The method of claim 53, wherein joining each of the top and bottom beams to each of the first and second side beams comprises attaching each end of each beam to a corresponding corner joining element.

55. The method of claim 54, wherein attaching each associated mounting rail to the frame structure comprises attaching the associated mounting rail between one of the first and second side beams and the center beam.

56. The method of claim 55, further comprising supporting a first end of the mounting rail on a first mounting ridge provided on said one of the first and second side beams and supporting a second end of the mounting rail on a second mounting ridge provided on the center beam.

57. The method of claim 55, wherein the attaching the associated mounting rail between one of the first and second side beams and the center beam comprises aligning mounting holes on each end surface of the associated mounting rail with mounting holes on one of the first and second side beams and the center beam, and placing a fastening element therethrough.

58. The method of claim 52, wherein providing the center beam between the top and bottom beams comprises attaching end flanges of the center beam to each of the top and bottom beams.

59. The method of claim 51, further comprising affixing a surface of the at least one associated one mounting rail to the bottom surface of each photovoltaic module.

60. The method of claim 59, wherein the affixing comprises applying an adhesive to one or both of the top surface of the mounting rail and the bottom surface of the photovoltaic module, and pressing the mounting rail and photovoltaic module together.

61. The method of claim 52, further comprising providing a plurality of structures affixed to the side beams for facilitating sliding installation of the mounting cartridge along a support rail.

62. The method of claim 61, further comprising sliding the mounting cartridge along the support rail to an installation location.
